(19) United States
(12) Patent Application Publication
(10) Pub. No.: US 2022/0395765 A1
(43) Pub. Date: Dec. 15, 2022

(54) Device for Purifying a Product and Method for Purifying a Product

(71) Applicant: KROHNE Messtechnik GmbH, Duisburg (DE)

(72) Inventors: Jan Förster, Essen (DE); Malte Brandenburg, Essen (DE)

(21) Appl. No.: 17/807,052

(22) Filed: Jun. 15, 2022

(30) Foreign Application Priority Data
Jun. 15, 2021 (EP) 21179562.0

(51) Int. Cl. B01D 9/00

(52) U.S. Cl. CPC B01D 9/0063; B01D 9/0013; B01D 9/0059; B01D 2009/0086

(57) ABSTRACT

A device for purifying a product by crystallization includes: a feed unit having a solution in which the total product concentration is substantially completely dissolved or a suspension with the total product concentration; a crystallization unit in which the product crystallizes and forms a solids content; a separation unit in which the crystallized product is separated from the solution or suspension; a temperature control unit for controlling temperature at least in the feed unit and/or the crystallization unit; and a control and evaluation unit that determines the total product concentration and/or the concentration of the solids content and/or the concentration of the dissolved product content and/or the concentration of an impurity content, taking into account the measured values of connected temperature sensors and of connected impedance sensors.

### TECHNICAL FIELD

The invention is based on a device for purifying a product by means of crystallization, wherein the product is preferably produced by a chemical method and wherein the product has an impurity content δ, comprising a feed unit with a solvent, wherein the product is fed to the device via the feed unit during operation, so that in the feed unit there is a solution in which a total product concentration α is substantially completely dissolved, or a suspension having the total product concentration α, a crystallization unit in which the product crystallizes during operation to form a solids content β, wherein a further content of the product is present as a dissolved product content γ, a separation unit, in which the crystallized product is separated from the solution or suspension, a temperature control unit, by means of which the temperature can be controlled at least in the feed unit and/or the crystallization unit, and further comprising a control and evaluation unit. Furthermore, the invention relates to a method for purifying a product with a device according to the invention, wherein the product is preferably produced by a chemical method, and wherein the product has an impurity content δ.

### BACKGROUND

In the production of products with chemical process technology (CVT), these products must be purified or separated from the carriers and/or catalysts required for the production in one of the final production steps in order to achieve a sufficiently high product purity. For such a separation or purification, different methods exist that are suitable for the respective substances and cannot necessarily be interchanged at will. One important method is the separation or purification by means of crystallization.

In crystallization, the product contaminated by the manufacturing process (referred to here as educt) is present in a feed unit completely dissolved in a solvent or finely dispersed as a heterogeneous mixture of substances. The total product concentration is referred to as α in the following. If the solution or suspension is brought to a supersaturated state in a crystallization unit, for example by cooling or by evaporation of solvent, crystal formation or crystal growth is stimulated and a portion of the previously dissolved product now crystallizes to solid. This solids content is referred to as β in the following, and the remaining dissolved or finely divided product concentration as γ. Since the total product concentration remains unchanged despite crystallization, α=β+γ.

During crystal growth, many of the impurities previously adhering to the educt are not reincorporated in the resulting solids and remain in the liquid phase. The crystallized product is then separated from the liquid phase in a separation unit. In this way, the final product is purified from unwanted impurities and is available in a very high purity. At the same time, the impurity concentration δ in the solution is increased. Since, in one design, the solution separated from the solid (as so-called mother liquor) is reused for dissolving the next portion of the contaminated product, the impurity concentration δ in the feed unit and the crystallization unit increases steadily in cyclic systems until the concentration is so high that too many impurities are incorporated during the crystal growth of the product to be purified, i.e., the purification effect of the process is reduced. As a result, the product is then no longer present in the required purity and must either pass through a purification process again or even be discarded. The former means an unnecessary expenditure of energy, the latter an undesired waste of resources.

Energy is required for the crystallization process. To dissolve the contaminated product, the solvent is heated, for example. In this way, a high proportion of the product can be dissolved in the solvent without the solution or suspension reaching saturation, since the saturation limit increases with rising temperature.

In the subsequent step of recrystallization, the solution or suspension is rapidly cooled down to a very low temperature (cooling crystallization) or heated to the boiling point (evaporation crystallization). In chemical process technology, temperature ramps of several 10° C. in a few minutes are often applied in the former case, for which a large cooling capacity is required. After reaching the target temperature for the crystallization process, the solution or suspension is then kept at the target temperature until the crystallization process is complete. The crystallized product is then removed at the separation unit. If the product is not held at the target temperature long enough, less product is crystallized than is technically possible, resulting in poor process efficiency. However, if the product is held at the target temperature longer than necessary, more cooling energy is applied than necessary, which also reduces the efficiency of the process.

It is therefore desirable to monitor the process of crystallization and in particular the course of crystal growth.

It is known from the publication CN 109030303 A to monitor the process of crystallization by measuring the electrical impedance.

### SUMMARY

Based on the prior art set forth, it is therefore an object of the present invention to provide a device for purifying a product by means of crystallization which ensures particularly efficient purification. Furthermore, it is an object of the invention to provide a particularly efficient method for purifying a product by means of crystallization.

According to a first teaching of the invention, the object is achieved by a device described at the outset in that a temperature sensor and an impedance sensor are arranged in each case at at least two locations of the device, wherein the temperature sensors and the impedance sensors are connected to the control and evaluation unit, and that the control and evaluation unit is designed such that, during operation, it determines the total product concentration α and/or the concentration of the solids content β and/or the concentration of the dissolved product content γ and/or the concentration of the impurity content δ, taking into account the measured values of the temperature sensors and of the impedance sensors.

According to the invention, it was recognized that process variables characterizing the crystallization process, such as, in particular, the total product concentration α and/or the concentration of the solids content β and/or the concentration of the dissolved product content γ and/or the concentration of the impurity content δ, can be efficiently captured and also monitored online if both the temperature and the electrical impedance are detected at at least two points in the process. In this regard, the invention takes into account that the crystallization process changes the electrical impedance, and thus the conductivity and/or permittivity of the solution or suspension.

If the temperature also changes in the course of crystallization, a change in electrical impedance attributable to the temperature change can be compensated for by measuring the temperature.

The invention thus has the advantage that the aforementioned desired variables total product concentration α and/or the concentration of the solids content β and/or the concentration of the dissolved product content γ and/or the concentration of the impurity content δ can be captured and monitored online, so that measures can be taken at an early stage if the monitored variables deviate from the expected target values or target ranges. Thus, the process of purifying a product can be controlled particularly efficiently.

According to a first design, a return unit is provided, wherein the separation unit is connected to the feed unit via the return unit, so that, during operation, the solution or the suspension flows through the feed unit into the crystallization unit into the separation unit and through the return unit back into the feed unit.

For example, the device according to the invention is designed as a tube comprising the different sections feed unit, crystallization unit, separation unit and optionally return unit. In addition, the device can also be a series of individual containers that are connected to each other. Furthermore, the device can likewise be designed as a single container. In this case, the individual units are implemented by the common container.

According to a next design, a first impedance sensor and a first temperature sensor are arranged in the feed unit and a second impedance sensor and a second temperature sensor are arranged in the crystallization unit and preferably a third impedance sensor and a third temperature sensor are arranged in the return unit, if present. With this design, the aforementioned parameters can be captured and monitored at various points in the process, thus ensuring particularly accurate monitoring of the crystallization process.

Particularly preferably, the device is designed in such a way that the control and evaluation unit carries out one of the methods described below during operation.

According to a second teaching of the present invention, the object described above is achieved by a method described in the introduction for purifying a product with one of the devices described above, wherein the product is preferably produced by a chemical method, and wherein the product has an impurity content δ, in that, in a preparatory step, the relationship between the electrical impedance of the solution or the suspension and the temperature and/or the total product concentration α in the solution or the suspension and/or the solids content β and/or the impurity content δ is captured, wherein a calibration matrix is determined from the captured relationship, and that, during operation of the device, the following steps are carried out:
in a feed step, the product is fed to the feed unit, wherein the product is placed in solution or suspension in the feed unit, or wherein the product is fed in solution or suspension to the feed unit,
wherein the temperature in the feed unit is adjusted such that the solution or suspension is in an undersaturated state,
starting crystallization in a crystallization step by bringing the solution or suspension to a supersaturated state, preferably by adjusting the temperature to a target temperature, wherein the total product concentration α in the crystallization unit is the sum of the crystallized solid β and the dissolved product content γ,
capturing the electrical impedance and temperature at at least two locations of the device in an impedance measurement step,
determining the total product concentration α and/or the solids content β and/or the dissolved product content γ and/or the impurity content δ in an analysis step from the electrical impedance, the measured temperature and the calibration matrix.

Adjusting the temperature is understood to mean heating or cooling the solution or the suspension.

The preparatory step is carried out before the device is put into operation or when the process parameters are changed, for example when the product to be purified is changed and/or when the solvent is changed. Through the measurements within the scope of the preparatory step, the process is characterized and parameterized with regard to all relevant relationships.

By measuring the impedance and temperature during crystallization, the aforementioned parameters can be determined and monitored online during purification. By measuring at at least two points in the process, the values measured at the individual points can be compared with each other with regard to their plausibility.

In addition, appropriate measures can be taken at an early stage if the monitored variables deviate from the desired values. This can significantly increase the efficiency of the purification process.

By monitoring the total product concentration α, this can be kept essentially constant during operation by appropriate replenishment of the product into the feed unit.

By monitoring the solids content β, the degree of crystallization of the product being purified can be determined and monitored. In this respect, the progress of the purification of the product can likewise be monitored online. Depending on the degree of crystallization and the desired crystal size, the crystallized product can be separated from the solution or suspension.

According to one design, by determining the impurity content δ in the mother liquor, it is monitored that the impurity content δ does not become too high, which, as described earlier, would lower the efficiency of the purification process.

According to one design, the impedance and temperature are continuously captured and monitored at various points in the process. According to a further design, the temperature and the impedance at the various points of the process are captured at regular or irregular intervals.

According to a further design, the same variable, for example the total product concentration α, is determined at the different points of the process. It is particularly advantageous if different variables are determined at different points of the process.

For example, the total product concentration α is determined and monitored in the feed unit and the solids content β is determined and monitored in the crystallization unit and optionally the impurity content δ is determined and monitored in the return unit.

Particularly preferably, at each measuring point where an impedance sensor and a temperature sensor are arranged, all relevant quantities total product concentration α and solids content β and dissolved product content γ and impurity content δ are determined and monitored.

To capture the relationship between the electrical impedance of the solution or suspension and the temperature and/or the total product concentration α in the solution or suspension and/or the solids content β and/or the impurity content δ, according to one design, a linear regression model is used. In this case, the measured values of the electrical permittivity εᵣ, and the temperature T are input parameters that are weighted so that the output parameter of the total product concentration α is obtained.

According to a further advantageous design of the method, in order to determine the total product concentration α and/or the solids content β and/or the dissolved product content γ and/or the impurity content δ, additional limiting conditions are taken into account which result from the arrangement of the temperature sensors and the impedance sensors in the process. For example, one limiting condition is that the total product concentration α, i.e., the sum of the solids content β and the dissolved content γ of the product is identical in the course of the process, especially in the feed unit and the crystallization unit. Another limiting condition is that the dissolved content γ of the product and the impurity content δ in the crystallization unit and in the optional recycle unit are almost identical. Another limiting condition is that the solids content β of the product in the optional return unit is approximately zero.

Particularly preferably, according to one design, compliance with at least one of the aforementioned limiting conditions is monitored, wherein the controlling of the purification process takes place depending on compliance with the at least one monitored boundary condition.

According to a next design of the method, the electrical impedance is used to determine the permittivity and/or the electrical conductivity of the solution or the suspension. It is thus exploited that the conductivity and/or permittivity of the solution or suspension changes when the product crystallizes.

According to a further preferred design, the time at which crystal formation changes to crystal growth is determined from the measured values of permittivity. For this purpose, the gradient of permittivity is determined. In principle, the gradient in the crystal growth phase is lower than the gradient in the crystal formation phase. If the gradient falls below a specified limit value, the crystal formation phase transitions to the crystal growth phase.

According to a further design of the method, the impurity concentration δ in the mother liquor is monitored, wherein a limit value for the impurity concentration δ is present in the device, and wherein fresh solvent is replenished to the feed unit or wherein the solvent is at least partially replaced when the impurity concentration exceeds a limit value. This design ensures that too much impurity does not collect in the solution or suspension, thereby reducing the efficiency of the purification process.

Another design of the method is characterized in that the product is replenished such that the total product concentration α remains substantially constant. An error due to a variation of the total product concentration α can thus be avoided.

The crystallization process of an organic product is described as a special design of the method according to the invention. This described process serves to purify the product. At the end of the production process, the product is not yet sufficiently pure. Here, the product comes out of the process with a purity of approx. 95%. The remaining 5% are impurities due to production residues such as catalysts. The present purity of 95% is not sufficient for further processing of the product and is therefore purified to at least 95.5%, preferably to at least 99.5% by means of the crystallization process. For other products, of course, other present and intended purity values apply here.

In the example described here, crystallization is carried out in a continuously operated process. For this purpose, the product dissolved in solvent at the end of the production process is fed into the crystallization unit, the so-called feed unit. In this example, the solution/suspension is present at a temperature of approx. 40° C. The solution/suspension now flows from the feed unit into the crystallization unit. The crystallization unit can be implemented in the simplest form, for example as a temperature-controlled tube. The temperature control serves to cool the solution/suspension in order to drive it into supersaturation and thus initiate the onset of crystallization. The length of the tube and the temperature control of the tube must be selected so that the solution/suspension flowing through this tube has reached or fallen below the temperature required for crystallization at the end of the tube. In the present example for the organic product, a temperature of about −20° C. or colder should be aimed for so that as little product as possible remains in liquid form in the solution/suspension and the efficiency of the process is thus high. The process also works with higher temperatures, but then less solid material is produced and the efficiency of the process is lower. At the end of the reactor, the solids are then separated from the remaining solution. This is done in the simplest way, for example, with the aid of a slotted strainer or a sieve, which is regularly removed and emptied.

Here, for example, at least two parallel lines could be implemented, through which the solution/suspension from the reactor flows alternately. While one sieve is emptied, the other one can filter.

Due to the continuous process, most of the solution remaining after this filtration is reheated to the temperature required for the feed unit to the crystallization unit. This necessary temperature is equal to the temperature of the solution/suspension at the end of the production process. Again, in the simplest case, this is done by a temperature-controlled pipe of sufficient length and temperature control. In order to avoid accumulation of liquid in the process, the return of the filtered solution is reduced by exactly the volume that corresponds to the volume of the solution/suspension entering the feed unit from the process minus the volume of the removed solid.

The monitoring of the crystallization process and the control of the process based on it, is now done by measuring the electrical impedance of the solution/suspension in at least two places in this example process. In the presently-described design, the capture of the product is measured in the feed unit. There, the measured electrical impedance, together with the temperature measured there, provides information about which total product concentration α is present in the feed unit.

From the multi-dimensional, in particular three-dimensional, calibration matrices, the total product concentration α can be determined within the measurement accuracy for this measuring point. Since the temperature is also known, it can then also be determined directly from the solubility curve, which is also known from the calibration, whether the product is completely in solution at this point, as desired, or whether solids content of the product are present. In the latter case, this results in the content of the product that is already present as a solid not being purified further in the crystallization process and thus contaminating the final product. For the example process, this would be an immense loss. Another useful measuring point in the example process is at the end of the crystallization unit. Here, the total product concentration α present is also determined from the measured electrical impedance. Logically, this must be equal to the value from the feed unit at this point. This framework condition allows the measurement of the electrical impedance to be compensated for interfering influences by equating the values at these two measuring points by offset shift. Furthermore, at the end of the crystallization unit, the solids content β can be quantified based on the measured temperature and the known solubility curve. In this way, it can be checked that the desired solids content β is actually formed in the crystallization unit. If too little solids content β is formed, the cooling of the crystallization unit is adjusted, in detail cooling is made stronger.

At both measuring points mentioned, the concentration of the dissolved impurity can also be determined with the aid of the three-dimensional calibration matrix. Thus, in the example process, it is possible to observe how the dissolved impurities accumulate as a result of continuous crystallization and the return of the filtered solution to the feed unit. It is useful to make measurements at both points because this improves the measurement uncertainty and is the only way to make statements about impurity concentration <1% in the described process. Recirculation of the filtered solution no longer makes sense if the concentration of impurities exceeds a critical level. This critical level can be determined in advance by laboratory analysis. Typical values for this critical level are in the range <10%. If the critical level is reached, the filtered solution is not recirculated but discarded and the feed unit is filled with clean solvent instead until the impurity concentration has dropped again to a value well below the critical level.

### BRIEF DESCRIPTION OF THE DRAWINGS

There is now a large number of possibilities for designing and further developing the device according to the invention and the method according to the invention.

Reference is made to the following description of preferred embodiments in conjunction with the drawings.

FIG. 1 illustrates a schematic embodiment of a device for purifying a product.

FIG. 2 illustrates an arrangement for impedance measurement.

FIG. 3 illustrates a device for determining the calibration matrix product.

FIG. 4 illustrates a measuring point matrix for characterizing the process.

FIG. 5 illustrates a correlation between the conductivity and the total product concentration.

FIG. 6 illustrates a correlation between permittivity and total product concentration.

FIG. 7 illustrates a model for determining the desired parameters solids content β, dissolved product content γ and impurity content δ.

FIG. 8 illustrates a relationship between temperature, conductivity and permittivity.

FIG. 9 illustrates an embodiment of a method for purifying a product.

FIG. 10 illustrates a further embodiment of a method for purifying a product.

### DETAILED DESCRIPTION

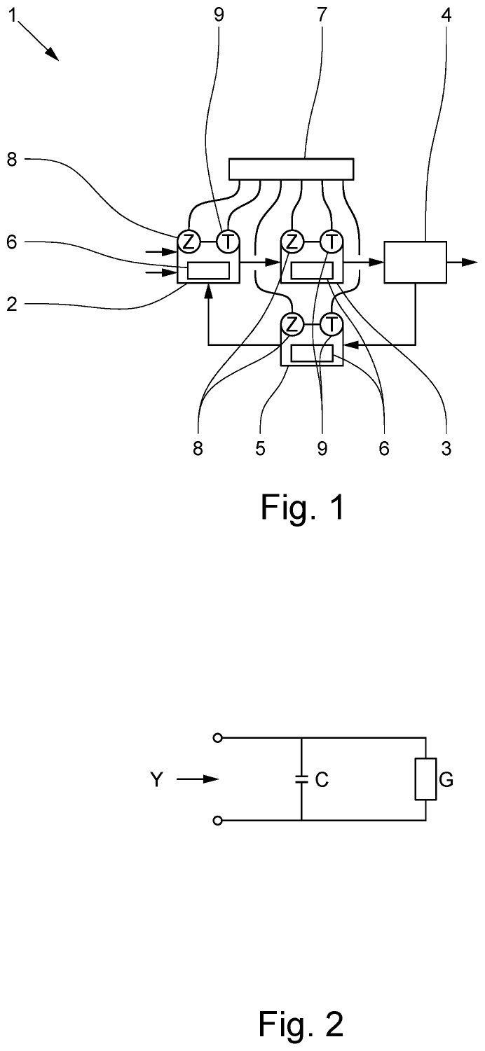

FIG. 1 shows a schematic embodiment of a device 1 for purifying a product, wherein the product is produced by means of chemical process engineering, and thus has an impurity content δ due to production.

The device 1 comprises a feed unit 2, wherein the feed unit 2 comprises a solvent, and wherein, during operation, the product is fed to the device 1 via the feed unit 2, such that in the feed unit 2 there is a solution in which a total product concentration α is substantially completely dissolved, or a suspension having the total product concentration α.

In addition, the device 1 comprises a crystallization unit 3 in which the product crystallizes during operation to form a solids content β, wherein a further content of the product is present as a dissolved product content γ.

Furthermore, the device 1 has a separation unit 4 in which the crystallized product is separated from the solution or suspension.

The separation unit 4 is connected to the feed unit 2 via a return unit 5, so that, during operation, the solution or the suspension is fed back to the feed unit 2. In addition, the crystallized part of the product is separated from the solution or the suspension in the separation unit 4.

A cyclic system is thus shown overall, in which the solution containing the product to be purified or the suspension containing the product to be purified flows through the device 1.

The temperature in the feed unit 2 and in the crystallization unit 3 and in the return unit 5 is controlled by a temperature control unit 6. During operation, the temperature in the feed unit 2 is controlled in such a way that the product is completely dissolved or finely dispersed. In the crystallization unit 3, the temperature is controlled in such a way that crystal formation and crystal growth of the product take place. In the return unit 5, the temperature is typically controlled such that the product is completely dissolved at the outlet to the feed unit 2.

Furthermore, the device 1 comprises a control and evaluation unit 7.

A temperature sensor 8 and an impedance sensor 9 are arranged in the feed unit 2, in the crystallization unit 3 and in the return unit 5, respectively, which determine the temperature and the impedance in the feed unit 2, the crystallization unit 3 and in the return unit 5, respectively, during operation.

The quantity to be determined or monitored, total product concentration α and/or solids content β and/or dissolved product content γ and/or impurity content δ, can be determined during operation from the measured values of impedance and temperature.

Due to the presence of the plurality of temperature sensors 8 and impedance sensors 9, in particular due to their arrangement in the process, further conditions can also be created which can be used to determine the previously mentioned parameters. By permanently determining these parameters, the crystallization process can be monitored particularly advantageously and controlled efficiently.

FIG. 2 shows an example of an arrangement for measuring the impedance of a liquid.

The parallel arrangement of a capacitance C and an electrical conductivity G is shown.

The electrical impedance Z is determined via the admittance Y. It holds true:

$$Y = \frac{1}{Z} \approx G + j ω C \approx \frac{1}{k} ( σ + j ω {ε}_{0} {ε}_{r} ) ,$$

where σ is the electrical conductivity and εᵣ is the permittivity.

Thus, both the electrical conductivity σ and the permittivity εᵣ of the medium can be determined from the measurement of the impedance.

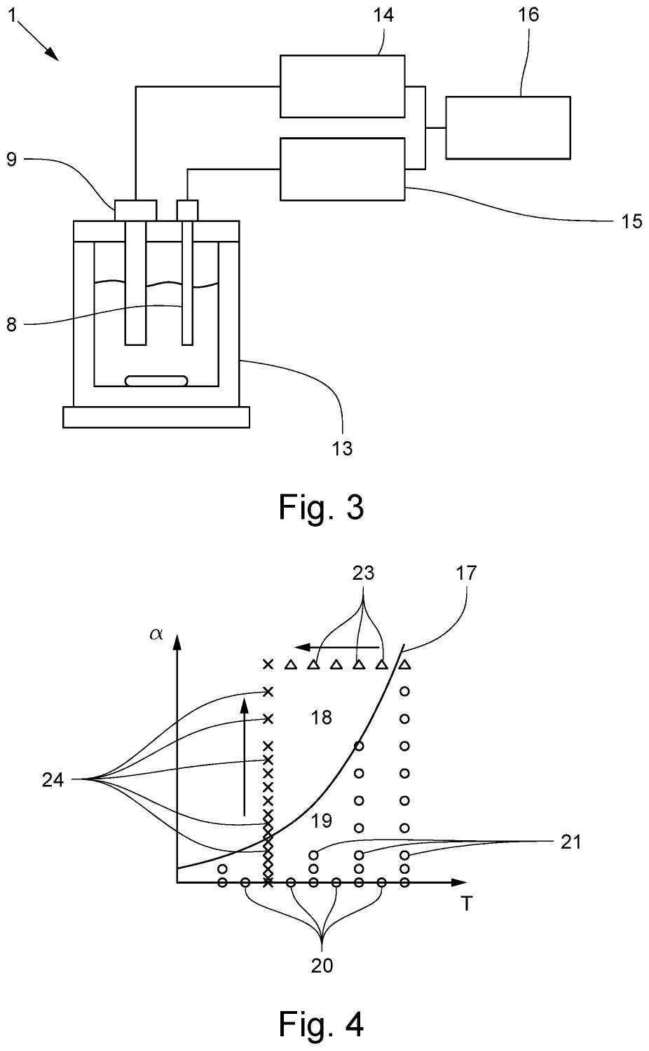

FIG. 3 shows the arrangement of a device for determining the calibration matrix of a product, wherein the product to be purified is arranged in a solvent in a container 13.

The device comprises an impedance sensor 9, which is designed as a coaxial sensor in the embodiment shown, for detecting the electrical impedance of the solution, and a temperature sensor 8, which is designed as a Pt 1000 or as a Pt 100 in the embodiment shown. Both sensors 8,9 are immersed in the solution or suspension. The impedance sensor 9 is connected to a vector network analyzer 14, and the temperature sensor 8 is connected to a multimeter 15. The network analyzer 14 and the multimeter 15 are in turn connected to a computer 16, which determines the calibration values based on the measured impedance.

FIG. 4 shows the solubility curve 17 of a product in a liquid medium. Knowledge of the solubility curve 17 of the product in the selected solvent is required in order to be able to deduce, on the basis of the measured temperature and the total product concentration α determined from the characteristic, whether and in what concentration the product is present in crystalline form in the suspension.

The solubility curve 17 of a product in the selected solvent is usually known and can therefore be taken as given. Above the solubility curve 17, the product is in the supersaturated state 18. Below the solubility curve, the product is in the undersaturated state 19. With higher total product concentration α, the temperature also increases to produce the supersaturated state 18.

In addition, measuring points are entered in the coordinate system, via which the system is characterized in a preparatory step.

The influence of the temperature on the electrical impedance without product concentration can be determined via the measuring points 20 along the x-axis. Knowledge about the influence of temperature on the electrical impedance in solution, i.e. in the fully dissolved state can be determined using the measuring points 21 in the undersaturated region for the same product concentrations at different temperatures. Knowledge about the influence of temperature on the electrical impedance of the product in suspension can be determined using the triangular measuring points 22, which have different temperatures for the same product concentration. In addition, knowledge of the effect of product concentration on electrical impedance can be obtained from the cross-shaped measuring points 24.

Furthermore, all characterizing measuring points are determined for different impurity contents δ, thus creating a multi-dimensional measuring point matrix for characterizing the system.

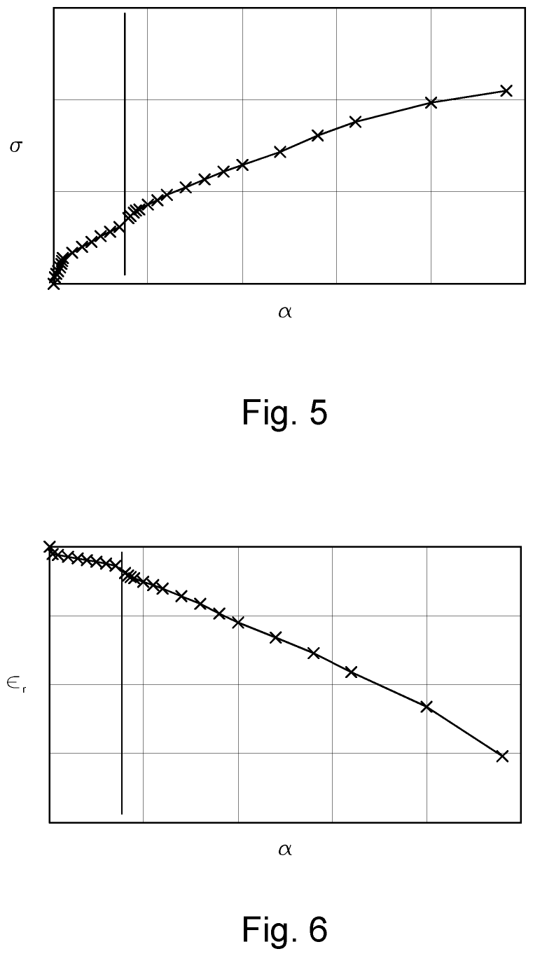

The relationships established by means of the measuring points 20, 21, 22, 23, 24 shown in FIG. 4 can be represented in the form of various characteristic curves and stored in the control and evaluation unit 7. FIGS. 5 and 6 show, as examples for an organic product, the dependence of the conductivity σ on the total product concentration α (FIG. 5) and the dependence of the permittivity εᵣ on the total product concentration α (FIG. 6). In each case, the onset of crystallization is marked by the vertical line. It can be seen that, in contrast to conductivity, permittivity changes more strongly dependent on total product concentration with onset of crystallization. From the slope of the permittivity, therefore, a statement can be made about the presence of crystals in the suspension.

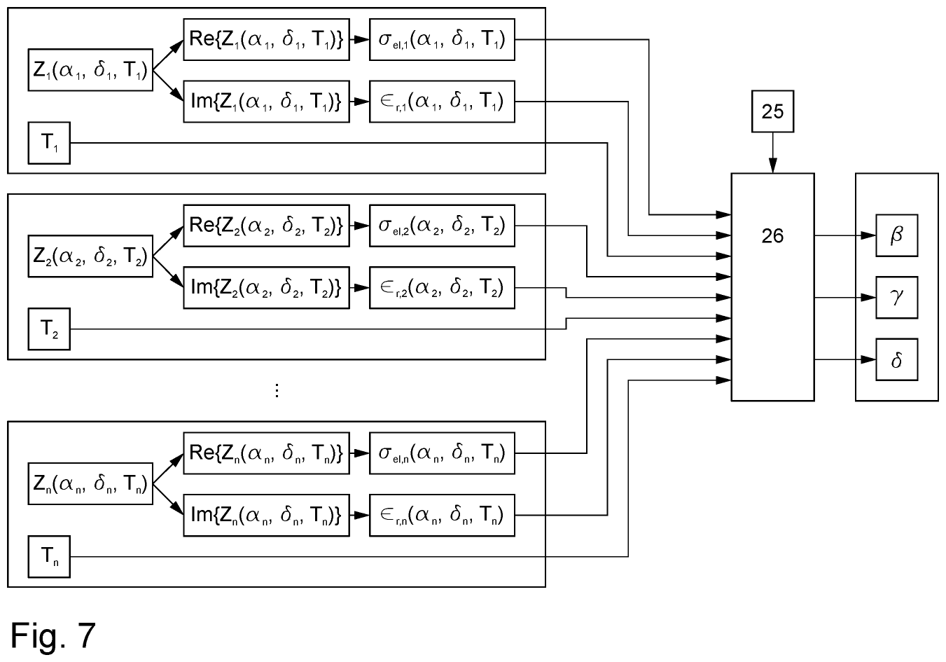

FIG. 7 shows a model for determining the desired parameters solids content β, dissolved product content γ, and impurity content δ based on the measured impedance Z₁, Z₂ to Zₙ, and the corresponding temperatures T₁, T₂ to Tₙ at n measuring points.

The measured electrical impedance at each measuring point exhibits a dependence on the total product concentration α, impurity δ, and temperature T. If the complex-valued electrical impedance is broken down into its real and imaginary parts, these also exhibit dependencies on α, δ and T, respectively. By linking at least two measuring points while simultaneously taking into account the temperature measured at these measuring points and adding a process model 26 generated from prior process knowledge 25, the target parameters ρ, γ and δ can be determined from the values of conductivity and permittivity.

By using more than two measuring points, the accuracy of the determined target parameters can be further improved, since, for example, measurement errors can be reduced by averaging or plausibility checks.

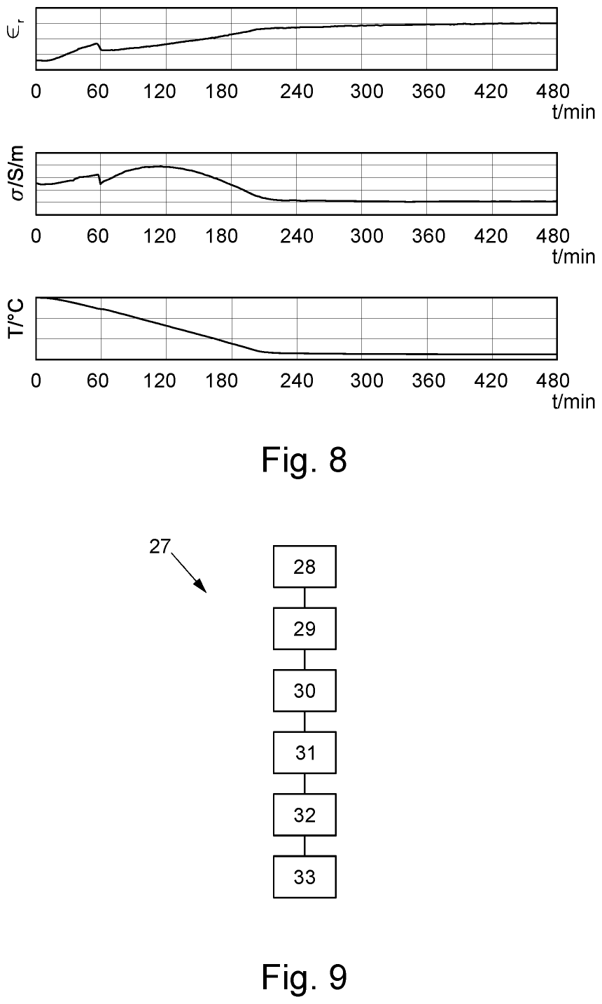

FIG. 8 shows the dependence of the electrical conductivity and the permittivity of a substance in a non-aqueous solution or suspension on the temperature. Here, for an initially completely dissolved substance, which was present in solution at 20% w, the temperature was reduced from 60° C. to −20° C., resulting in crystallization of the substance at approx. 44° C. The onset of crystallization can be seen by a jump in the curve of electrical conductivity and permittivity. The curve also shows that the permittivity gradient changes after the onset of crystallization but remains linear, while the electrical conductivity gradient varies with respect to the mathematical sign.

When an approximately constant temperature is reached in the crystallization unit, the permittivity slowly approaches a final value. In this phase, there is a slow crystal growth, in which it is not the amount of crystalline material increases, but the crystal size itself. Based on this fading curve, an operator of the process can decide at which point the crystallization process is technically complete and the desired amount and size of crystals is present.

FIG. 9 shows a first embodiment of a method 27 for purifying a product with a device 1, wherein the device 1 is designed as described in FIG. 1, wherein the product is produced by a chemical process, and wherein the product has an impurity content δ.

In a preparatory step 28 of the method 27, the relationship between the electrical impedance of the solution or suspension and the temperature and/or the product concentration α in the solution or suspension and/or the degree of crystallization p and/or the impurity concentration δ is captured.

From the acquired relationship, a calibration matrix is determined 29 by which the desired parameters are determined during operation.

During operation of the apparatus, the following steps are carried out:

In a feed step 30, the product is fed to the feed unit, wherein the product is placed in solution or suspension in the feed unit, or wherein the product is fed in solution or suspension to the feed unit.

The temperature in the feed unit is thereby adjusted such that the solution or the suspension is in an undersaturated state.

In a crystallization step 31, crystallization is stimulated by adjusting the temperature, wherein the total product concentration α is the sum of the recrystallized solid β and the dissolved product content γ.

In an impedance measurement step 32, the electrical impedance and temperature are measured in at least two locations of the device.

In addition, in an analysis step 33, the total product concentration α and/or the solids content β and/or the dissolved product content γ and/or the impurity content δ is determined from the electrical impedance, the measured temperature and the calibration matrix.

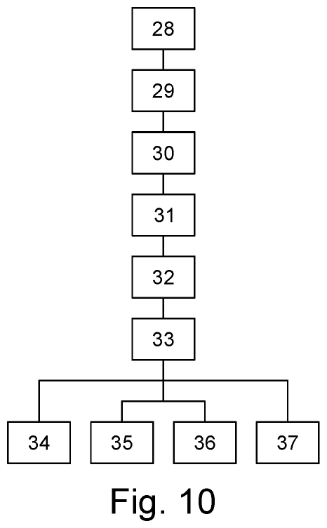

FIG. 10 shows another embodiment of the method according to the invention. Based on the determination of the total product concentration α and/or the solids content β and/or the dissolved product content γ and/or the impurity content δ described earlier, the control of the process is adjusted to increase efficiency.

Specifically, the crystalline solids content β is removed 34 when there is a sufficient degree of crystallization and a sufficient crystal size.

In addition, solvent is replenished 35 into the feed unit 2 or the solvent is partially replaced 36 when the impurity concentration exceeds a limit.

Furthermore, product is supplied 37 into the feed unit 2 so that the total product concentration α in the solution or suspension remains substantially constant during operation.

1. A device for purifying a product by means of crystallization, wherein the product is produced by a chemical method and wherein the product has an impurity content, comprising:
a feed unit with a solvent, wherein the product is fed to the device via the feed unit during operation, so that in the feed unit there is a solution in which the total product concentration is substantially completely dissolved, or a suspension with the total product concentration;
a crystallization unit, in which the product crystallizes during operation and thus forms a solids content, wherein a further content of the product is present as a dissolved product content;
a separation unit, in which the crystallized product is separated from the solution or suspension;
a temperature control unit by means of which the temperature can be controlled at least in the feed unit and/or the crystallization unit;
and further comprising a control and evaluation unit;
wherein a temperature sensor and an impedance sensor are arranged in each case at at least two locations of the device;
wherein the temperature sensors and the impedance sensors are connected to the control and evaluation unit; and
wherein the control and evaluation unit is designed such that, during operation, it determines the total product concentration and/or the concentration of the solids content and/or the concentration of the dissolved product content and/or the concentration of the impurity content, taking into account the measured values of the temperature sensors and of the impedance sensors.

2. The device according to claim 1, wherein the separation unit is connected to the feed unit via a return unit, so that, during operation, the solution or the suspension flows through the feed unit into the crystallization unit into the separation unit and through the return unit back into the feed unit.

3. The device according to claim 1, wherein a first impedance sensor and a first temperature sensor are arranged in the feed unit:
wherein a second impedance sensor and a second temperature sensor are arranged in the crystallization unit; and
wherein a third impedance sensor and a third temperature sensor are arranged in the return unit, if present.

4. The device according to claim 1, wherein the control and evaluation unit carries out a method during operation, the method including the following steps:
a preparatory step, in which the relationship between the electrical impedance of the solution or the suspension and the temperature and/or the total product concentration in the solution or the suspension and/or the solids content and/or the impurity content is captured;
wherein a calibration matrix is determined from the captured relationship; and
wherein, during operation of the device, the following steps are carried out;
a feed step, in which the product is fed to the feed unit, wherein the product is placed in solution or suspension in the feed unit, or wherein the product is fed in solution or suspension to the feed unit;
wherein the temperature in the feed unit is adjusted such that the solution or suspension is in an undersaturated state;
starting crystallization in a crystallization step by bringing the solution or suspension to a supersaturated state, by adjusting the temperature to a target temperature, wherein the total product concentration in the crystallization unit is the sum of the crystallized solids and the dissolved product content;
capturing the electrical impedance and temperature at at least two locations of the device in an impedance measurement step;
determining the total product concentration and/or the solids content and/or the dissolved product content and/or the impurity content in an analysis step from the electrical impedance the measured temperature, and the calibration matrix.

5. A method for purifying a product with a device including a feed unit with a solvent, wherein the product is fed to the device via the feed unit during operation, so that in the feed unit there is a solution in which the total product concentration is substantially completely dissolved, or a suspension with the total product concentration, a crystallization unit, in which the product crystallizes during operation and thus forms a solids content, wherein a further content of the product is present as a dissolved product content, a separation unit, in which the crystallized product is separated from the solution or suspension, a temperature control unit by means of which the temperature can be controlled at least in the feed unit and/or the crystallization unit, and further comprising a control and evaluation unit, wherein a temperature sensor and an impedance sensor are arranged in each case at at least two locations of the device wherein the temperature sensors and the impedance sensors are connected to the control and evaluation unit, and wherein the control and evaluation unit is designed such that, during operation, it determines the total product concentration and/or the concentration of the solids content and/or the concentration of the dissolved product content and/or the concentration of the impurity content, taking into account the measured values of the temperature sensors and of the impedance sensors, wherein the product is produced by a chemical method, and wherein the product has an impurity content, the method comprising:
in a preparatory step, the relationship between the electrical impedance of the solution or the suspension and the temperature and/or the total product concentration in the solution or the suspension and/or the solids content and/or the impurity content is captured;
wherein a calibration matrix is determined from the captured relationship; and
wherein, during operation of the device, the following steps are carried out:
in a feed step, the product is fed to the feed unit, wherein the product is placed in solution or suspension in the feed unit, or wherein the product is fed in solution or suspension to the feed unit;
wherein the temperature in the feed unit is adjusted such that the solution or suspension is in an undersaturated state;
starting crystallization in a crystallization step by bringing the solution or suspension to a supersaturated state, by adjusting the temperature to a target temperature, wherein the total product concentration in the crystallization unit is the sum of the crystallized solids and the dissolved product content;
capturing the electrical impedance and temperature at at least two locations of the device in an impedance measurement step;
determining the total product concentration and/or the solids content and/or the dissolved product content and/or the impurity content in an analysis step from the electrical impedance, the measured temperature, and the calibration matrix.

6. The method according to claim 5, wherein for determining the total product concentration and/or the solids content and/or the dissolved product content and/or the impurity content, limiting conditions resulting from the arrangement of the temperature sensors and the impedance sensors in the process are additionally taken into account.

7. The method according to claim 5, wherein the permittivity and/or the electrical conductivity of the solution or the suspension is determined with the electrical impedance.

8. The method according to claim 5, wherein the crystal growth is monitored after the onset of crystallization.

9. The method according to claim 5, wherein the impurity concentration in the mother liquor is monitored;
wherein a limit value for the impurity concentration is stored in the device; and
wherein solvent is replenished into the feed unit or the solvent is at least partially replaced if the impurity concentration exceeds the limit value.

10. The method according to claim 5, wherein the product is replenished in such a way that the total product concentration in the solution or in the suspension remains substantially constant.
